(19) United States
(12) Patent Application Publication
(10) Pub. No.: US 2019/0123763 A1
(43) Pub. Date: Apr. 25, 2019

(54) DATA COMPRESSION ENGINE FOR DICTIONARY BASED LOSSLESS DATA COMPRESSION

(71) Applicant: Intel Corporation, Santa Clara, CA (US)

(72) Inventors: Sailesh BISSESSUR, Phoenix, AZ (US); Patrick FLEMING, Slatt Wolfhill (IE); Lokpraveen MOSUR, Gilbert, AZ (US); David K. CASSETTI, Tempe, AZ (US); Stephen T. PALERMO, Chandler, AZ (US); Smita KUMAR, Chandler, AZ (US); Pradnyesh S. GUDADHE, Chandler, AZ (US); Naveen LAKKAKULA, Chandler, AZ (US); Brian WILL, Phoenix, AZ (US)

(21) Appl. No.: 16/228,300

(22) Filed: Dec. 20, 2018

(51) Int. Cl. H03M 7/30; G06F 16/953; G06F 16/2455

(52) U.S. Cl. CPC H03M 7/3086; G06F 16/24568; G06F 16/953

(57) ABSTRACT

A compression engine includes sets of independent search engines. The sets of independent search engines concurrently perform searches for a longest match in a stream of uncompressed data. The searches are distributed amongst the sets of independent search engines on byte boundaries to load balance the use of the search engines.

### FIELD

This disclosure relates to data compression and in particular to dictionary based lossless data compression.

### BACKGROUND

Data can be compressed using a lossless or lossy compression algorithm to reduce the amount of data required to store or transmit digital content. A Lossless compression algorithm reconstructs an original message exactly from a compressed representation of the original message.

A dictionary coder is a class of lossless data compression algorithms that operates by searching for a match between text in the message to be compressed and a set of strings in a ‘dictionary’ maintained by an encoder. When the encoder finds a match for a string in the message, it substitutes the string with a reference to the string's position in the dictionary. Lossless data compression algorithms include Lempel-Ziv (LZ) algorithms such as LZ77, LZ4 and LZ4 Streaming (LZ4S). Programs used for file compression and decompression such as, GNU zip (gzip), GIF (Graphics Exchange Format) and Zstandard use LZ lossless data compression algorithms.

The LZ algorithms dynamically build a dictionary while uncompressed data is received, and compressed data is transmitted. No additional data is transmitted with the compressed data to allow the compressed data to be uncompressed. The dictionary is dynamically rebuilt while the compressed data is decompressed. The LZ algorithms support text, images, and videos.

An encoder that uses a LZ lossless data compression algorithm to compress an input stream data uses prior input data information of the input data stream that can be referred to as “history”. The LZ lossless data compression algorithm searches the history for a string that matches each next portion of the input data stream. If such a match is found, the encoder encodes the matched next portion of the input data using a reference (offset and length) to the matching string in the history.

Otherwise, the encoder encodes a next character of the input data stream as a raw data code or a “literal” that designates the character as plain text or clear text. The just encoded portion of the input data stream is then added to the history, and is included in the search to match the next portion of the input data stream. Often, the history is stored in a fixed size, sliding window type buffer, from which the oldest data exits as new data from the input data stream is added.

Accordingly, with an encoder that uses a LZ lossless data compression algorithm, an input data stream is encoded with respect to preceding data in that same input data stream. The encoder that uses a LZ lossless data compression algorithm achieves compression of the input data stream because the reference (offset and length) to the matching string can be much smaller than a portion of the input data stream that the reference represents.

### BRIEF DESCRIPTION OF THE DRAWINGS

Features of embodiments of the claimed subject matter will become apparent as the following detailed description proceeds, and upon reference to the drawings, in which like numerals depict like parts, and in which:

FIG. 1 is a block diagram illustrating processing stages in a single stream compression engine to compress a received uncompressed data stream (also referred to as “clear text” or plaintext) to provide a compressed data stream;

FIG. 2 is a block diagram of the hash stage of the single stream compression engine shown in FIG. 1;

FIG. 3A is a block diagram of the longest match search stage in the compression circuitry shown in FIG. 1;

FIG. 3B is a table illustrating the 64 concurrent searches for bytes [63:0] in the set of search engines in FIG. 3A;

FIG. 4 illustrates an example of a scoreboard entry in a scoreboard queue;

FIG. 5 is a block diagram of the encode stage in the compression engine shown in FIG. 1;

FIG. 6 is a block diagram of a portion of the scoreboard queue entries in the set of scoreboard queues illustrating literals and tokens stored in the scoreboard queue entries;

FIG. 7 is a flowgraph illustrating a method to perform a search for a longest match to compress a stream of clear text (‘literal’) bytes; and

FIG. 8 is a block diagram of an embodiment of a server in a cloud computing system that includes the compression engine shown in FIG. 1.

Although the following Detailed Description will proceed with reference being made to illustrative embodiments of the claimed subject matter, many alternatives, modifications, and variations thereof will be apparent to those skilled in the art. Accordingly, it is intended that the claimed subject matter be viewed broadly, and be defined only as set forth in the accompanying claims.

### DESCRIPTION OF EMBODIMENTS

Lossless performance is usually stated in terms of throughput and compression ratio. Lossless performance is dependent on the effectiveness of pre-processing the input data stream string in a timely manner. Searches that take too long can reduce throughput if the compression engine stalls.

A search of incoming data for a longest match with historical data is optimized by load balancing search engines. Data compression performance is improved by distributing search engines grouped together in pools that are organized to orchestrate searches on byte boundaries within an input data stream. Load balancing search engines include a set of search engines. Each Set of search engines is assigned to start on an assigned (specific) input data stream byte location (a byte boundary within the input data stream) and each search engine can start from any of the assigned input data stream byte locations, operate independently and concurrently. A search engine execution priority is based on age (“position”) of a search result entry in a search result queue, with a scoreboard queue age of “0” assigned the highest priority.

Load balancing searches for a longest match in the input data stream maximizes utilization without stalling the compression engine by searching multiple consecutive locations of the input data stream in one processor clock cycle for a match of multiple bytes.

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in to provide a concise discussion of embodiments of the present inventions.

A server is a computer or device that can be dedicated to managing network resources. Typically, a server can monitor performance metrics that include key performance indicators to understand the state of server. Performance metrics that can be monitored include Central Processor Unit (CPU) utilization, memory utilization and network throughput.

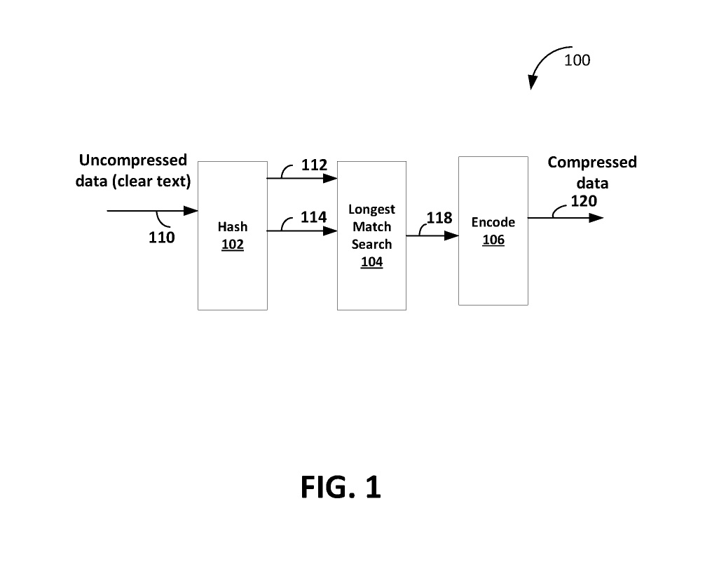

FIG. 1 is a block diagram illustrating processing stages in a single stream compression engine 100 to compress a received uncompressed data stream (also referred to as plaintext or “clear text”) 110 to provide compressed data 120. The single stream compression engine 100 includes circuitry to initiate multiple searches of the incoming uncompressed data 110 to find and concurrently encode duplicate sequences to improve throughput of the single stream compression engine 100.

The single stream compression engine 100 can support various lossless compression algorithms, including Zstandard, LZ77, LZ4, LZ4s, and DEFLATE. The basic principle of a compression algorithm is to store input data in a buffer while attempting to find the longest data string from the previously stored plaintext or “clear text” data in the buffer that can match the input data in the buffer. If a match is found, the data string match is encoded as a <length, offset> token. If a match is not found, the input data is left as is (that is, a “Literal” (also referred to as plaintext or “clear text”)).

The single stream compression engine 100 has three processing stages: hash stage 102, longest match search stage 104, and encode stage 106. In the hash stage 102, a search is performed for previously encountered data strings in the received uncompressed data. In the longest match search stage 104 a search for the longest string match length in the uncompressed data using the previously encountered data strings received from the hash stage 102 is performed. In the encode stage 106 search results from the longest match search stage 104 are encoded in the appropriate compressed format.

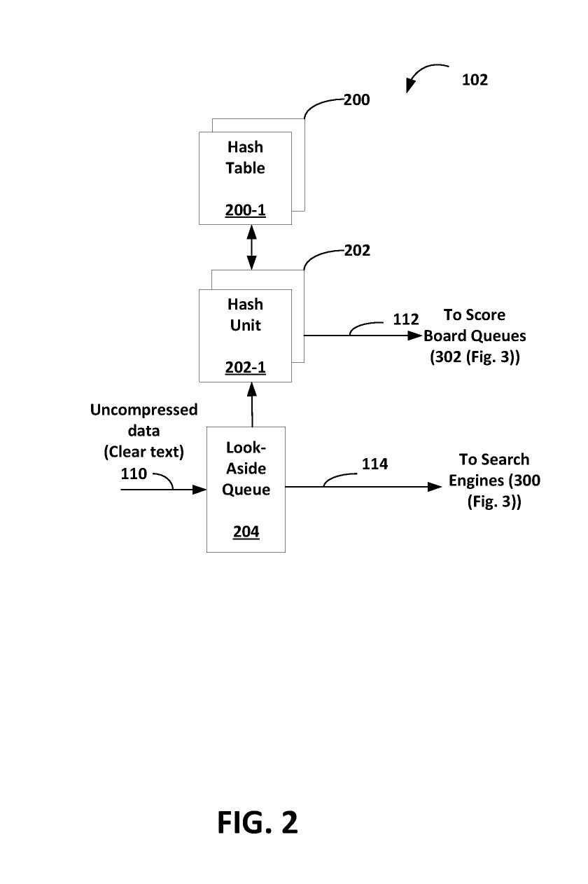

FIG. 2 is a block diagram of the hash stage 102 of the single stream compression engine 100 shown in FIG. 1. The single stream compression engine 100 supports a plurality of hash functions that are performed in the hash stage 102. The hash stage 102 includes hash tables 200, hash units 202 and a look-aside-queue 204.

When uncompressed data 110 to be compressed in the single stream compression engine 100 is received, the uncompressed data 110 is first written in the Look-Aside-Queue 204. During normal operation, as uncompressed data 110 is received, the received uncompressed data 110 to be compressed in the single stream compression engine 100 is inserted at the tail of the Look-Aside-Queue 204. In an embodiment, the Look-Aside-Queue 204 can store 512-bytes of uncompressed data.

The Look-Aside-Queue 204 has four pointers, a head pointer, a tail pointer, a retirement pointer and a current pointer. The tail pointer stores the location (entry) in the Look-Aside-Queue 204 in which data can be inserted in the Look-Aside-Queue 204. The Look-Aside-Queue Head Pointer and Look-Aside-Queue current pointer identify the entries in the Look-Aside-Queue that store data that has been processed by the single stream compression engine 100 and can be flushed from the Look-Aside-Queue 204. The number of bytes that are flushed from the Look-Aside-Queue 204 can vary and is dependent on the lossless compression algorithm used by the single stream compression engine 100 to perform the compression.

Each of m hash units 202 performs a hash function in parallel to map n-bytes from the Look-Aside-Queue 204 to an index to one of p hash tables 200. The hash function is performed on n consecutive bytes starting with the byte stored in an entry Look-Aside-Queue 204 at the location stored in the current pointer for the Look-Aside-Queue 204. The number of bytes (n) is dependent on the lossless compression algorithm. For example, n is 4 for LZ4 which uses a 4-byte hash function and n is 3 for DEFLATE which uses a 3-byte hash function.

An example will be discussed for an embodiment using the DEFLATE compression algorithm where m is 8, n is 3 and p is 16 and the Look-Aside-Queue 204 stores a clear text data string that has 14 consecutive bytes labeled “ABCDEFGHIJKLMN”. Each of the 8 hash units 202 concurrently performs a hash function on one of the eight sets of 3-bytes from the Look-Aside-Queue 204. For example, for the 14 consecutive bytes labeled “ABCDEFGHIJKLMN”, the 8 sets of 3-bytes are: “ABC”, “BCD”, “CDE”, “DEF”, “EFG”, “FGH”, GHI, and “HIJ”. The result of each hash function on each one of the sets of 3-bytes is a 12-bit index for an entry in hash tables 200.

The hash Units 202 use the 12-bit indices from the 8 hash units 202 to read the 16 hash tables 200, an entry in the hash tables 200 stores a pointer to an entry in a dictionary if the set of 3-bytes has an entry in the dictionary. The dictionary is a buffer that stores clear text data that has been processed by the single stream compression engine 100. The current pointer for the Look-Aside-Queue is incremented by 8 to process the next 8 bytes starting with “I” in the clear text data string.

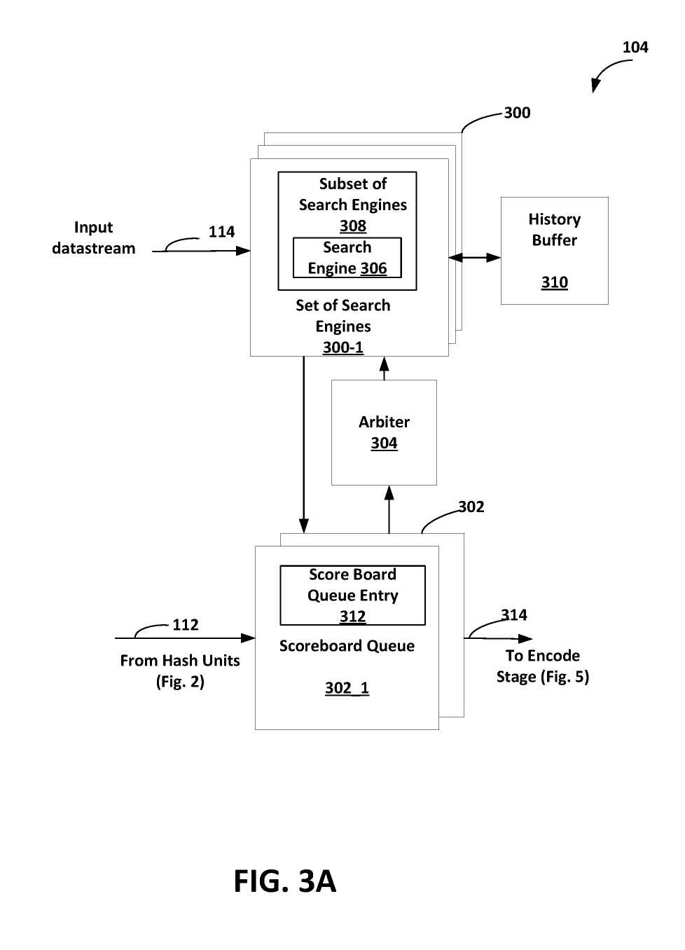

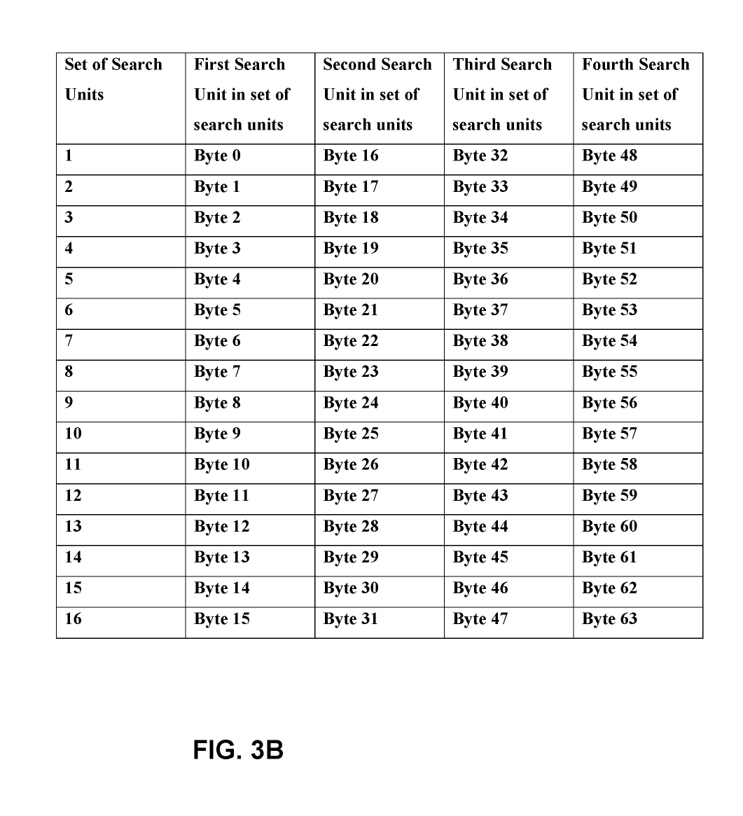

FIG. 3A is a block diagram of the longest match search stage 104 in the single stream compression circuitry 100 shown in FIG. 1. The longest match search stage 104 includes a set of search engines 300, scoreboard queues 302, an arbiter 304 and a history buffer 310.

The history buffer 310 is a buffer that is used to store clear text data (“history data”) that has been processed by the single stream compression engine 100. The clear text data stored in the history buffer 310 can be referred to as a “dictionary”. The “dictionary” is created on the fly during compression and re-created on the fly during decompression. The history buffer 310 acts a sliding window/circular queue. When the history buffer 310 is full, the oldest data at the head of the history buffer 310 is overwritten by data read from the Look-Aside-Queue 204 (FIG. 2) that has been processed by the single stream compression engine 100. History data can also include data stored in the Look-Aside-Queue 204 in addition to the data stored in the history buffer 310.

After performing the hash functions, the hash units 202 (FIG. 2) store information pertinent to a given byte 112 in the uncompressed data 110 in the corresponding scoreboard queue entry 312 for the byte. The information pertinent to a given byte 112 can be the address in the history buffer 310 associated with a hash key stored in the hash units 202.

The size of the history buffer 310 is dependent on the compression standard that is being used by the single stream compression engine 100. For example, in an embodiment, the size of the History buffer 310 is 32 Kilo Bytes (KB) for DEFLATE compression and 32 KB for LZ4.

The single stream compression engine 100 has M hash tables 200 that can be accessed in parallel to store and retrieve up to M addresses for the history buffer 208 for a single hash table index. Retrieving up to M addresses for the history buffer 208 allows up to M concurrent search operations for a given byte position. In an embodiment, M is sixteen.

The set of search engines 300 may also be referred to as a “pool” of search engines 300. The set of search engines 300 has multiple subsets (“groups”) of search engines 308. The multiple subsets of search engines 308 in the set of search engines 300 allows the set of search engines 300 to concurrently operate on multiple consecutive byte locations in the input data stream 114.

A search engine 306 in the set of search engines 300 performs a search in the clear text data stored in the history buffer 310 starting at one of the M address stored in a scoreboard queue entry 312 for a match for the data string formed using the data read from the Look-Aside-Queue 204 (FIG. 2). If a match is found, the matched data string is replaced with a reference token (for example, as a <length, distance> token) in an entry in a search results queue which can be referred to as a scoreboard queue entry 312 in the scoreboard queues 302 in accordance with the particular compression standard.

In an embodiment, the single stream compression engine 100 has two hundred and fifty six search engines 306 organized as sixteen sets of search engines 300. Each set of search engines 300 has four subsets of search engines 308 and each subset of search engines 308 has four search engines 306. Each set of search engines 300 includes circuitry to concurrently operate on multiple byte locations in the input data stream 114. The single stream compression engine 100 can concurrently operate on up to one hundred and twenty eight byte locations (with eight bytes concurrently processed by each of the sixteen sets of search units), thereby storing search results in up to 128 scoreboard Queue Entries.

An arbiter 304 communicatively coupled to the scoreboard queues 302 monitors the set of scoreboard queues 302 and triggers the appropriate set of search engines 300 to perform a search

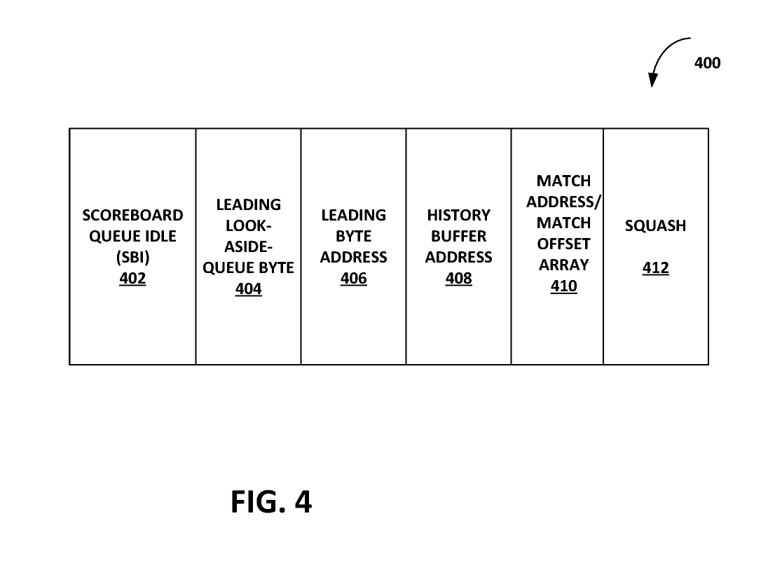

In an embodiment, the single stream compression engine 100 has sixty four search engines 306 organized as sixteen sets of search engines 300. The single stream compression engine 100 can concurrently search in up to sixty four locations in the history buffer 310 (with four bytes concurrently processed by each of the sixteen sets of search units), thereby storing search results in up to sixty four scoreboard Queue Entries 312. There are sixty four scoreboard entries 312 in the scoreboard queue 302 and a set of four scoreboard queues 302 per set of search engines 300. After the Search Engines 306 complete the search in the history buffer 310, the result of the search is stored in a scoreboard entry 312 in scoreboard queues 302. The fields in the scoreboard entry 312 will be described later in conjunction with FIG. 4.

An eight parallel byte search of eight consecutive bytes from the Look-Aside-Queue 204 is performed per CPU clock cycle. Eight consecutive locations of n-bytes from the Look-Aside-Queue 204 are hashed in a single clock in the hash stage 102. Per resource (scoreboard queues 302 and search engines 300) availability, the single stream compression engine 100 issues an eight byte parallel search in the 8 hash units 202 every CPU clock cycle. The hash units 202 read eight history buffer addresses stored in the locations in the hash tables 200 identified by the indices stored in the hash units 202. When the corresponding scoreboard queues 302 become available, the hash units 202 update the scoreboard queues with the history buffer addresses read from the hash tables 200.

The arbiter 304 uses the information stored in the scoreboard queues 302 to dispatch searches to be performed by sets of search engines 300. The sets of search engines 300 update the scoreboard queues until the search is complete and store the results of the search in the scoreboard queues 302.

FIG. 3B is a table illustrating the sixty four concurrent searches for sixty four bytes [63:0] in the sets of search engines 300 in FIG. 3A. Four bytes of the input data stream 114 can be searched concurrently by the set of search engines 300, with sixteen sets of four-bytes processed in eight consecutive CPU clock cycles (eight bytes per CPU clock cycle) resulting in sixty four concurrent searches for bytes [63:0] in the set of search engines 300 shown in FIG. 3A.

A search for eight consecutive bytes from the Look-Aside-Queue (Byte[0:7]-]->Byte[8:15]-> . . . ->Byte[56:63]) using sixteen sets of search engines 300 can be started every clock cycle. For example, the first set of eight bytes uses set of search units[0:7], the second set of eight bytes uses set of search units[8:15], the third set of eight bytes uses set of search units[0:7], the fourth set of eight bytes uses set of search units[8:15]. The pipeline timing is dependent on the number of valid history buffer addresses in the history buffer 310 and the data string match length.

After the clear text data has been compressed in the single stream compression engine 100, the clear text data at the head of the Look-Aside-Queue 204 is flushed from the Look-Aside-Queue 204 to the history buffer 310 using the head pointer of the Look-Aside-Queue 204.

The set of search engines 300 compare the received input data stream 114 with the data stored in the history buffer 310, placing string comparison results into scoreboard Queues 302 while concurrently encoding data, using results from the scoreboard queues 302, into a single compressed data stream.

FIG. 4 illustrates an example of a scoreboard entry 312 in scoreboard queues 302. The scoreboard entry 312 includes a plurality of fields. A scoreboard queue Idle (SBI) field 402 can be a one-bit field, the state of the bit (for example, set to logical ‘1’) indicates that the scoreboard queue 302 is in use. The Leading Look-Aside-Queue Byte (LQB) field 404 stores the first byte of the n-byte hash that was hashed. The Leading Byte Address (LQA) field 406 stores the Leading Byte Address (LQA) in the Look-Aside-Queue 204 that was hashed, for example, the data stored in a location in Look-Aside-Queue 204 to compare against the data stored in location(s) in the history buffer 310.

The history buffer Address field 408 stores history buffer addresses read from the hash tables 200 by the hash units 202. The history buffer addresses are used for search operations. The Match Address[n]/Match Offset Array[n] field 410 stores a list of search results that are used by the delayed match mode circuitry 502 to encode the data stream.

The Squash bit (SQH) field 412 can be a one-bit field, a state of the bit (for example, set to logical ‘1’) to indicate that the leading Look-Aside-Queue Byte stored in Leading Look-aside-queue Byte (LQB) field 404 has already been used by a previous match.

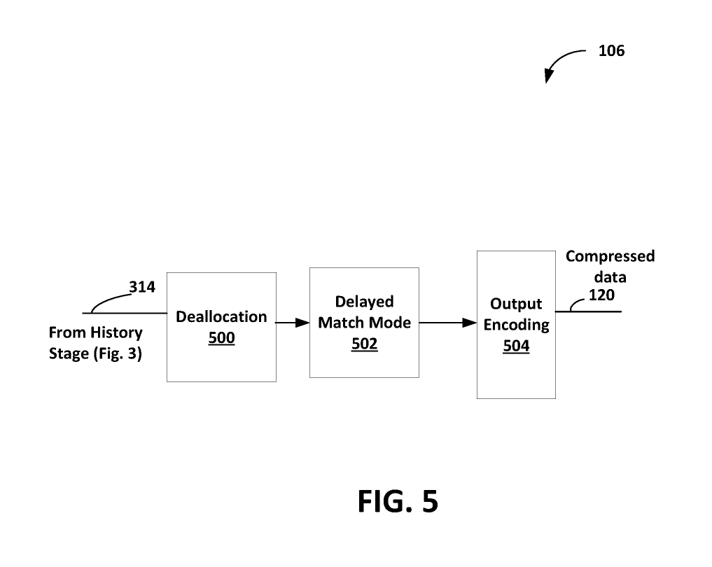

FIG. 5 is a block diagram of the encode stage 106 in the single stream compression engine 100 shown in FIG. 1. The encode stage 106 includes deallocation circuitry 502, delayed match mode circuitry 504 and output encoding circuitry 506.

In the encode stage 106 the search results that are stored in the scoreboard queues 302 are encoded in a compressed format. The results stored in a scoreboard queue entry 400 are resolved to select the longest match and the scoreboard queue entry is deallocated by deallocation circuitry 500. The Delayed Match Mode circuitry 504 encodes the search results into an optimum compression stream by using the merged results of adjacent scoreboard queue entries 312 to generate the compressed data 120 output from the single stream compression engine 100. The delayed match mode circuitry 502 also updates the Retirement Pointer for the Look-Aside-Queue 204.

The deallocation circuitry 502 deallocates the data from the Look-Aside-Queue 204 into the history buffer 208. The output encoding circuitry 506 translates the compressed data stream dependent on the selected compression algorithm: Static DEFLATE, LZ77, LZ4, or LZ4s.

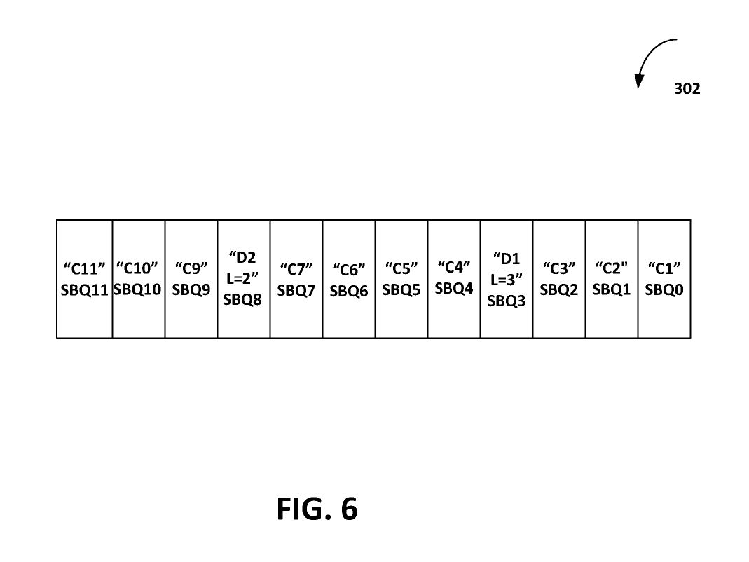

FIG. 6 is a block diagram of a portion of the scoreboard queue entries 312 in the set of scoreboard queues 302 illustrating literals and tokens stored in the scoreboard queue entries 312.

If a scoreboard queue Entry [x] with a match length of “n” is selected for encoding, the delayed match mode circuitry 502 sets the Squash bit 412 in scoreboard queue Entries[x+1:x+n−1]. The delayed match mode circuitry 502 also updates the Retirement Pointer to Look-Aside-Pointer current pointer+“n”. If a literal is selected from a scoreboard queue entry 312, the Retirement Pointer is incremented by 1.

In the example shown in FIG. 6, scoreboard queues entries SBQ3 and SBQ8 store a <length, offset> token. The other scoreboard queue entries SBQ0-SBQ2, SBQ4-SBQ7 and SBQ9-SBQ11 store literals. The encoding processes starts with scoreboard queues entries SBQ0 which stores a literal. The literals stored in SBQ0-SBQ2 are transmitted as literals in the compressed data 120. SBQ3 stores a length “3” and an offset D1, the token <3, D1> is transmitted in the compressed data 120 instead of SBQ4-SBQ5 and the squash bit is set in scoreboard queue entries SBQ4-SBQ5 to indicate that these bytes are not to be transmitted in the compressed data 120. SBQ8 stores a length “2” and an offset D2, the token <3, D2> is transmitted in the compressed data 120 instead of SBQ9 and the squash bit is set in scoreboard queue entries SBQ9 to indicate that these bytes are not be transmitted in the compressed data 120.

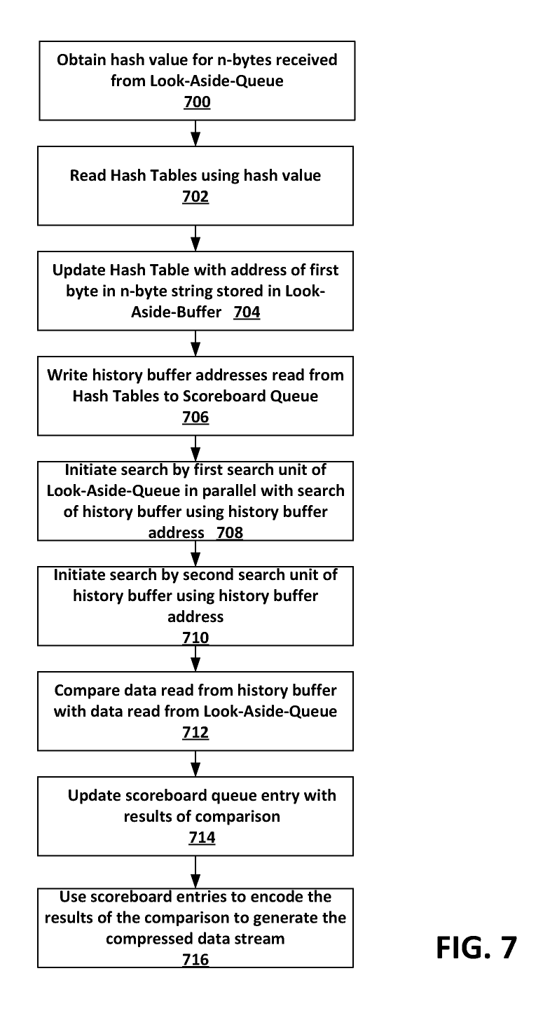

FIG. 7 is a flowgraph illustrating a method to perform a search for a longest match to compress a stream of clear text (‘literal’) bytes.

At block 700, a hash function is performed by hash units 202 on n-bytes of clear text received from the Look-Aside-Queue 204 to provide hash value(s) for the n-bytes. Processing continues with block 702.

At block 702, the hash table 200 is read using the hash value to obtain a history buffer Address for a location in the history buffer 310. In an embodiment in which there are M hash tables, each of the M hash tables 200 are read using the hash value in parallel to provide M history buffer Addresses for the history buffer 310. In an embodiment, M is 16. Processing continues with block 704.

At block 704, the hash table 200 is updated with the address in the Look-Aside-Queue 204 of the first byte in the n-byte string received from the Look-Aside-Queue 204. Processing continues with block 706.

At block 706, each of the M history buffer addresses is written to the corresponding scoreboard queue entry 312 in the set of scoreboard queues 302. Processing continues with block 708.

At block 708, a first search engine 306 initiates a read of the Look-Aside-Queue 204 in parallel with a read of the history buffer 310 using the history buffer Address. Processing continues with block 710.

At block 710, a second search engine 306 initiates a read of the history buffer 310 using another history buffer address. Processing continues with block 712.

At block 712, the data read from the history buffer 310 is compared with the data read from the Look-Aside-Queue 204. The time to perform the comparison is dependent on search depth, match length and access latency of the history buffer 310. Processing continues with block 714.

At block 714, the scoreboard queue entry 312 is updated with the results of the comparison, with a token or literal as discussed in conjunction with FIG. 6. Processing continues with block 716.

At block 716, the delayed match mode circuitry 502 uses the scoreboard queue entries 312 to encode the results of the comparison into the compressed data 120. After the results have been encoded into the compressed data 120, the deallocation circuitry 500 deallocates the scoreboard queue entries 312.

The effectiveness and performance of the compression performed by the single stream compression engine 100 is dependent on the ability to load balance the input data stream to identify the longest string to encode. A set (“pool”) of independent search engines 300 is assigned to specific input data stream byte locations to distribute searches on byte boundaries thereby to load balance the use of search engines 306 to minimize stalling effects of waiting for previous searches to complete. Advantages include increased throughput of a single compression stream, improved latency of a single compression task, reduced overall number of application context switches resulting in decreased latency, reduced cache and memory bandwidth by increasing the performance and increased client response time, and reduced server context switching.

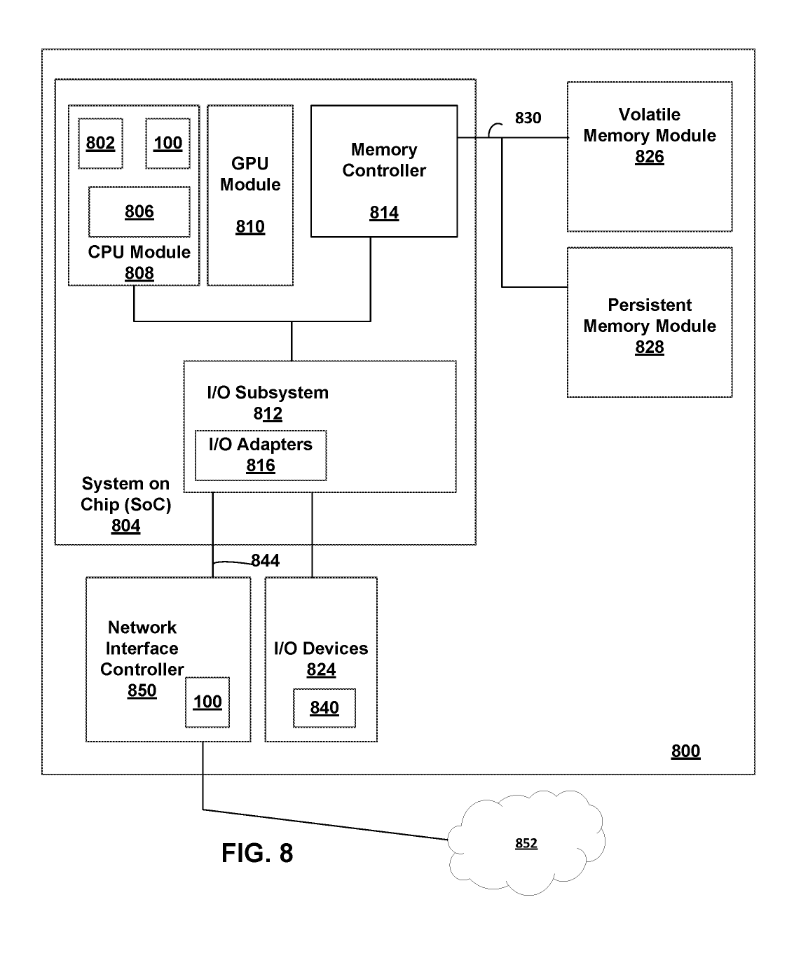

FIG. 8 is a block diagram of an embodiment of a server 800 in a cloud computing system that includes single stream compression engine 100. Server 800 includes a system on chip (SOC or SoC) 804 which combines processor, graphics, memory, and Input/Output (I/O) control logic into one SoC package. The I/O adapters 816 may include a Peripheral Component Interconnect Express (PCIe) adapter that is communicatively coupled over bus 844 to a network interface controller 850. The network interface controller 850 can include a compression engine to compress data received from network 852.

The SoC 804 includes at least one Central Processing Unit (CPU) module 808, a memory controller 814, and a Graphics Processor Unit (GPU) module 810. In other embodiments, the memory controller 814 may be external to the SoC 804. The CPU module 808 includes at least one processor core 802 and a level 2 (L2) cache 806 and single stream compression engine 100.

Although not shown, the processor core 802 may internally include one or more instruction/data caches (L1 cache), execution units, prefetch buffers, instruction queues, branch address calculation units, instruction decoders, floating point units, retirement units, etc. The CPU module 808 may correspond to a single core or a multi-core general purpose processor, such as those provided by Intel® Corporation, according to one embodiment. In an embodiment the SoC 804 may be a standalone CPU such as an Intel® Xeon® Scalable Processor (SP), an Intel® Xeon® data center (D) SoC, or a smart NIC accelerator card format.

The memory controller 814 may be coupled to a persistent memory module 828 having at least one persistent memory integrated circuit and a volatile memory module 826 having at least one volatile memory integrated circuit via a memory bus 830. A non-volatile memory (NVM) device (integrated circuit) is a memory whose state is determinate even if power is interrupted to the device. In one embodiment, the NVM device can comprise a block addressable memory device, such as NAND technologies, or more specifically, multi-threshold level NAND flash memory (for example, Single-Level Cell (“SLC”), Multi-Level Cell (“MLC”), Quad-Level Cell (“QLC”), Tri-Level Cell (“TLC”), or some other NAND). A NVM device can also comprise a byte-addressable write-in-place three dimensional cross point memory device, or other byte addressable write-in-place NVM device (also referred to as persistent memory), such as single or multi-level Phase Change Memory (PCM) or phase change memory with a switch (PCMS), NVM devices that use chalcogenide phase change material (for example, chalcogenide glass), resistive memory including metal oxide base, oxygen vacancy base and Conductive Bridge Random Access Memory (CB-RAM), nanowire memory, ferroelectric random access memory (FeRAM, FRAM), magneto resistive random access memory (MRAM) that incorporates memristor technology, spin transfer torque (STT)-MRAM, a spintronic magnetic junction memory based device, a magnetic tunneling junction (MTJ) based device, a DW (Domain Wall) and SOT (Spin Orbit Transfer) based device, a thyristor based memory device, or a combination of any of the above, or other memory.

Volatile memory is memory whose state (and therefore the data stored in it) is indeterminate if power is interrupted to the device. Dynamic volatile memory requires refreshing the data stored in the device to maintain state. One example of dynamic volatile memory (device or integrated circuit) includes DRAM (Dynamic Random Access Memory), or some variant such as Synchronous DRAM (SDRAM). A memory subsystem as described herein may be compatible with a number of memory technologies, such as DDR3 (Double Data Rate version 3, original release by JEDEC (Joint Electronic Device Engineering Council) on Jun. 27, 2007). DDR4 (DDR version 4, initial specification published in September 2012 by JEDEC), DDR4E (DDR version 4), LPDDR3 (Low Power DDR version3, JESD209-3B, August 2013 by JEDEC), LPDDR4) LPDDR version 4, JESD209-4, originally published by JEDEC in August 2014), WIO2 (Wide Input/Output version 2, JESD229-2 originally published by JEDEC in August 2014, HBM (High Bandwidth Memory, JESD325, originally published by JEDEC in October 2013, DDR5 (DDR version 5, currently in discussion by JEDEC), LPDDR5 (currently in discussion by JEDEC), HBM2 (HBM version 2), currently in discussion by JEDEC, or others or combinations of memory technologies, and technologies based on derivatives or extensions of such specifications. The JEDEC standards are available at www.jedec.org.

The Graphics Processor Unit (GPU) module 810 may include one or more GPU cores and a GPU cache which may store graphics related data for the GPU core. The GPU core may internally include one or more execution units and one or more instruction and data caches. Additionally, the Graphics Processor Unit (GPU) module 810 may contain other graphics logic units that are not shown in FIG. 1, such as one or more vertex processing units, rasterization units, media processing units, and codecs.

Within the I/O subsystem 812, one or more I/O adapter(s) 816 are present to translate a host communication protocol utilized within the processor core(s) 802 to a protocol compatible with particular I/O devices. Some of the protocols that I/O adapter(s) 816 may be utilized for translation include Peripheral Component Interconnect (PCI)-Express (PCIe); Universal Serial Bus (USB); Serial Advanced Technology Attachment (SATA) and Institute of Electrical and Electronics Engineers (IEEE) 1594 “Firewire”.

The I/O adapter(s) 816 may communicate with external I/O devices 824 which may include, for example, user interface device(s) including a display and/or a touch-screen display 840, printer, keypad, keyboard, communication logic, wired and/or wireless, storage device(s) including hard disk drives (“HDD”), solid-state drives (“SSD”) 818, removable storage media, Digital Video Disk (DVD) drive, Compact Disk (CD) drive, Redundant Array of Independent Disks (RAID), tape drive or other storage device. The storage devices may be communicatively and/or physically coupled together through one or more buses using one or more of a variety of protocols including, but not limited to, SAS (Serial Attached SCSI (Small Computer System Interface)), PCIe (Peripheral Component Interconnect Express), NVMe (NVM Express) over PCIe (Peripheral Component Interconnect Express), and SATA (Serial ATA (Advanced Technology Attachment)).

Additionally, there may be one or more wireless protocol I/O adapters. Examples of wireless protocols, among others, are used in personal area networks, such as IEEE 802.15 and Bluetooth, 4.0; wireless local area networks, such as IEEE 802.11-based wireless protocols; and cellular protocols.

It is envisioned that aspects of the embodiments herein can be implemented in various types of computing and networking equipment, such as switches, routers and blade servers such as those employed in a data center and/or server farm environment. Typically, the servers used in data centers and server farms comprise arrayed server configurations such as rack-based servers or blade servers. These servers are interconnected in communication via various network provisions, such as partitioning sets of servers into Local Area Networks (LANs) with appropriate switching and routing facilities between the LANs to form a private Intranet. For example, cloud hosting facilities can typically employ large data centers with a multitude of servers. Each blade comprises a separate computing platform that is configured to perform server-type functions, that is, a “server on a card.” Accordingly, each blade includes components common to conventional servers, including a main printed circuit board (main board) providing internal wiring (i.e., buses) for coupling appropriate integrated circuits (ICs) and other components mounted to the board. These components can include the components discussed earlier in conjunction with FIG. 8.

Flow diagrams as illustrated herein provide examples of sequences of various process actions. The flow diagrams can indicate operations to be executed by a software or firmware routine, as well as physical operations. In one embodiment, a flow diagram can illustrate the state of a finite state machine (FSM), which can be implemented in hardware and/or software. Although shown in a particular sequence or order, unless otherwise specified, the order of the actions can be modified. Thus, the illustrated embodiments should be understood only as an example, and the process can be performed in a different order, and some actions can be performed in parallel. Additionally, one or more actions can be omitted in various embodiments; thus, not all actions are required in every embodiment. Other process flows are possible.

To the extent various operations or functions are described herein, they can be described or defined as software code, instructions, configuration, and/or data. The content can be directly executable (“object” or “executable” form), source code, or difference code (“delta” or “patch” code). The software content of the embodiments described herein can be provided via an article of manufacture with the content stored thereon, or via a method of operating a communication interface to send data via the communication interface. A machine readable storage medium can cause a machine to perform the functions or operations described, and includes any mechanism that stores information in a form accessible by a machine (e.g., computing device, electronic system, etc.), such as recordable/non-recordable media (e.g., read only memory (ROM), random access memory (RAM), magnetic disk storage media, optical storage media, flash memory devices, etc.). A communication interface includes any mechanism that interfaces to any of a hardwired, wireless, optical, etc., medium to communicate to another device, such as a memory bus interface, a processor bus interface, an Internet connection, a disk controller, etc. The communication interface can be configured by providing configuration parameters and/or sending signals to prepare the communication interface to provide a data signal describing the software content. The communication interface can be accessed via one or more commands or signals sent to the communication interface.

Various components described herein can be a means for performing the operations or functions described. Each component described herein includes software, hardware, or a combination of these. The components can be implemented as software modules, hardware modules, special-purpose hardware (e.g., application specific hardware such as Intel® QuickAssist Technology, application specific integrated circuits (ASICs), digital signal processors (DSPs), programmable acceleration such as field-programmable gate arrays (FPGAs), etc.), embedded controllers, hardwired circuitry, etc.

Besides what is described herein, various modifications can be made to the disclosed embodiments and implementations of the invention without departing from their scope.

Therefore, the illustrations and examples herein should be construed in an illustrative, and not a restrictive sense. The scope of the invention should be measured solely by reference to the claims that follow.

What is claimed is:

1. An apparatus comprising:
memory to store a data stream to be compressed; and
a plurality of sets of independent search engines, the plurality of sets of independent search engines to concurrently perform searches for a longest match in the data stream, each set of independent search engines to start a search in the data stream at an assigned location in the data stream.

2. The apparatus of claim 1, wherein the assigned location is a byte boundary within the data stream.

3. The apparatus of claim 1, wherein the searches are distributed amongst the sets of independent search engines to load balance use of the sets of independent search engines.

4. The apparatus of claim 1, wherein a number of search engines in one of the sets of independent search engines is 16.

5. The apparatus of claim 1, wherein a number of sets of search engines is 16.

6. The apparatus of claim 1, wherein the data stream to be compressed using a lossless data compression algorithm.

7. The apparatus of claim 6, wherein the lossless data compression algorithm is algorithm is one of Lempel-Ziv (LZ)77, LZ4 or LZ4 Streaming (LZ4S).

8. A method comprising:
storing, a data stream to be compressed in a memory; and
concurrently performing, by a plurality of sets of independent search engines, searches for a longest match in the data stream, each set of independent search engines to start a search in the data stream at an assigned location in the data stream.

9. The method of claim 8, wherein the assigned location is a byte boundary within the data stream.

10. The method of claim 8, wherein the searches are distributed amongst the sets of independent search engines to load balance use of the sets of independent search engines.

11. The method of claim 8, wherein a number of search engines in one of the sets of independent search engines is 16.

12. The method of claim 8, wherein a number of sets of search engines is 16.

13. The method of claim 8, wherein the data stream to be compressed using a lossless data compression algorithm.

14. The method of claim 13, wherein the lossless data compression algorithm is one of Lempel-Ziv (LZ)77, LZ4 or LZ4 Streaming (LZ4S).

15. A system comprising:
a memory module, the memory module comprising at least one volatile memory integrated circuit, the volatile memory integrated circuit to store a data stream to be compressed; and
a plurality of sets of independent search engines, the plurality of sets of independent search engines to concurrently perform searches for a longest match in the data stream, each set of independent search engines to start a search in the data stream at an assigned location in the data stream.

16. The system of claim 15, wherein the assigned location is a byte boundary within the data stream.

17. The system of claim 15, wherein the searches are distributed amongst the sets of independent search engines to load balance use of the sets of independent search engines.

18. The system of claim 15, wherein a number of search engines in one of the sets of independent search engines is 16.

19. The system of claim 15, wherein a number of sets of search engines is 16.

20. The system of claim 15, wherein the data stream to be compressed using a lossless data compression algorithm.
